(19) United States
(12) Patent Application Publication
(10) Pub. No.: US 2026/0035262 A1
(43) Pub. Date: Feb. 5, 2026

(54) METHODS FOR SYNTHESIZING AND/OR PURIFYING MOLYBDENUM COMPOUNDS AND RELATED COMPOSITIONS AND RELATED SYSTEMS

(71) Applicant: ENTEGRIS, INC., Billerica, MA (US)

(72) Inventors: David M. Ermert, Danbury, CT (US); Bryan C. Hendrix, Danbury, CT (US)

(21) Appl. No.: 19/281,532

(22) Filed: Jul. 25, 2025

Related U.S. Application Data
(60) Provisional application No. 63/677,388, filed on Jul. 30, 2024.

(51) Int. Cl. C01G 39/04; C23C 16/14

(52) U.S. Cl. CPC C01G 39/04; C23C 16/14; C01P 2006/80

(57) ABSTRACT

Methods for synthesizing and/or purifying molybdenum compounds are provided. A method comprises obtaining a reagent; obtaining a metal trioxide compound; and contacting the reagent and the metal trioxide compound sufficient to form a reaction product comprising a molybdenum compound. Related compositions, related systems, and other related methods are provided, among other things.

### CROSS-REFERENCE TO RELATED APPLICATIONS

This application claims the benefit under 35 USC 119 of U.S. Provisional Patent Application No. 63/677,388, filed Jul. 30, 2024, the disclosure of which is hereby incorporated herein by reference in its entirety.

### FIELD

This disclosure generally relates to methods for synthesizing and/or purifying molybdenum compounds, and related compositions and related systems, among other things.

### BACKGROUND

The presence of contaminants in precursor vapors is undesirable in precursor delivery applications, for example in semiconductor fabrication and manufacturing. Reducing the presence of contaminants in the precursor vapors remains an ongoing challenge. Contaminants can include particles and/or vapors.

### SUMMARY

Some embodiments relate to a method. In some embodiments, the method comprises obtaining a reagent. In some embodiments, the reagent comprises at least one of a first metal halide compound, a second metal halide compound, a third metal halide compound, or any combination thereof. In some embodiments, the method comprises obtaining a metal trioxide compound of the formula: MO₃, where: M is W or Mo. In some embodiments, the method comprises contacting the reagent and the metal trioxide compound sufficient to form a reaction product of the formula: MO₂X₂, where: M is W or Mo; and X is a halide.

Some embodiments relate to a composition. In some embodiments, the composition comprises a compound of the formula: MO₂X₂, where: M is W or Mo; and X is a halide. In some embodiments, the compound has a purity of at least 99.99969% by weight as determined by inductively coupled plasma mass spectrometry (ICP-MS).

Some embodiments relate to a system. In some embodiments, the system comprises a vessel. In some embodiments, the vessel is configured for delivering a precursor vapor to a vapor deposition apparatus. In some embodiments, the vessel comprises a precursor comprising a compound of the formula: MO₂X₂, where: M is W or Mo; and X is a halide. In some embodiments, the precursor is contained in the vessel at a temperature and a pressure sufficient for the compound to have a density of 4 g/cm³ or less. In some embodiments, the compound has a purity of at least 99.99969% by weight as determined by inductively coupled plasma mass spectrometry (ICP-MS).

### BRIEF DESCRIPTION OF THE DRAWINGS

Reference is made to the drawings that form a part of this disclosure, and which illustrate embodiments in which the materials and methods described herein can be practiced.

FIG. 1 is a schematic diagram of a flowchart of a method of synthesis, according to some embodiments.

FIG. 2 is a Fourier-Transform Infrared (FTIR) spectrum for MoO₂Cl₂, according to some embodiments.

FIG. 3 is a ThermoGravimetric Analysis (TGA) for MoO₂Cl₂, according to some embodiments.

FIG. 4 is a Powder X-ray Diffraction (PXRD) pattern of MoO₂Cl₂ collected on sample prepared in a sealed capillary at 25° C. according to some embodiments.

FIG. 5 is a ThermoGravimetric Analysis (TGA) of MoO₂Cl₂ performed using platinum (Pt) pans and a temperature ramp rate of 10° C. per min according to some embodiments.

FIG. 6 is a closed-pan Differential Scanning calorimetry (DSC) of MoO₂Cl₂ using a temperature ramp rate of 5° C. per min according to some embodiments.

### DETAILED DESCRIPTION

Methods for synthesizing and/or purifying molybdenum compounds, including, for example and without limitation, molybdenum oxy halide compounds, among others, are provided herein. In some embodiments, a method for synthesizing and purifying a molybdenum compound, with high purity, in a single step, is provided. The methods disclosed herein may employ non-toxic reagents. The methods disclosed herein do not require use of chlorine gas and offer a synthetic route at comparatively reduced pressures. The methods disclosed herein utilize low melting point solid reagents, including, for example and without limitation, eutectic mixtures, among others, and thus offer a synthetic route at comparatively lower reaction temperatures. Compared to conventional methods which are performed at elevated temperature and elevated pressures, and require the use of chlorine gas, the methods disclosed herein are useful for synthesizing molybdenum compounds in a way that limits the impurity profile, minimizes and/or avoids presence of trace metals and/or water or moisture, among other things.

As used herein, the term “metal” refers to at least one of an alkali metal, an alkaline earth metal, a transition metal, a post-transition metal, or any combination thereof. In some embodiments, the metal comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof. The charge(s) of the metal cations are known and, for simplicity, thus are not repeated here; however, it will be appreciated that the metal cations can have any known charge.

As used herein, the term “halide” refers to a —Cl, —Br, —I, or —F.

As used herein, the term “eutectic mixture” refers to a composition comprising a first substance and a second substance, wherein the composition has a melting point that is less than a melting point of each of the first substance and the second substance.

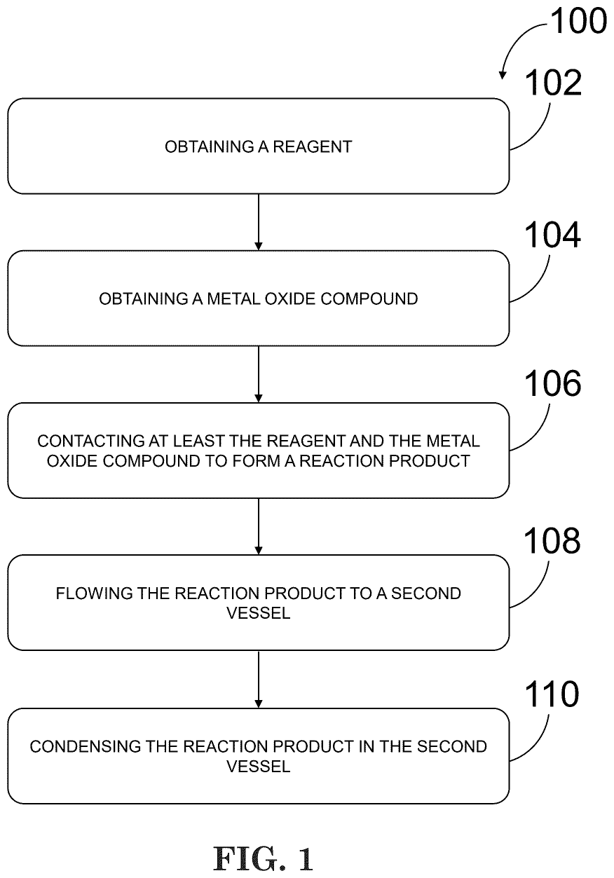

FIG. 1 is a schematic diagram of a flowchart of a method, according to some embodiments. As shown in FIG. 1, in some embodiments, the method comprises one or more of the following steps: obtaining 102 a reagent; obtaining 104 a metal trioxide compound; contacting 106 the reagent and the metal trioxide compound sufficient to form a reaction product; flowing 108 the reaction product from a vessel to a second vessel; and 110 condensing the reaction product in the second vessel.

At step 102, in some embodiments, the method comprises obtaining a reagent.

The reagent may comprise at least one of a first metal halide compound, a second metal halide compound, a third metal halide compound, or any combination thereof. In some embodiments, the reagent comprises the first metal halide compound and the second metal halide compound. In some embodiments, the reagent comprises the first metal halide compound, the second metal halide compound, and the third metal halide compound. In some embodiments, the first metal halide compound and the second metal halide compound form a eutectic mixture. In some embodiments, the reagent comprises the first metal halide compound, the second metal halide compound, and the third metal halide compound form a eutectic mixture. It will be appreciated that additional metal halide compounds may be present in the reagent, optionally so as to form a eutectic mixture, without departing from the scope of this disclosure.

In some embodiments, the first metal halide compound comprises a compound of the formula:

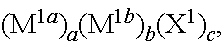

where:
M^{1a} and M^{1b} are each independently a first metal;
X¹ is a first halide;
a is 0 to 6;
b is 0 to 6; and
c is at least 1.

For brevity, it will be appreciated that a, b, and c may vary within the ranges provided herein to balance charges without departing from the scope of this disclosure. It will further be appreciated that a, b, and c may each independently be an integer value or a fractional value without departing from the scope of this disclosure.

In some embodiments, the first metal halide compound comprises a compound of the formula:

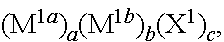

where:
M^{1a} is an alkali metal, an alkaline earth metal, or a transition metal;
M^{1b} is Sn or Al;
X¹ is Cl, Br, I or F;
a is at least 1;
b is at least 1; and
c is at least 1.

In some embodiments, M^{1a} is Li, Na, K, Mg, or Ca.

In some embodiments, the first metal halide compound comprises at least one of LiSnCl₃, NaSnCl₃, KSnCl₃, LiAlCl₄, NaAlCl₄, KAlCl₄, or any combination thereof.

In some embodiments, the second metal halide compound comprises a compound of the formula:

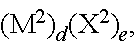

where:
M² is a second metal;
X² is a second halide;
d is 1 to 6; and
e is 1 to 6.

For brevity, it will be appreciated that d and e may vary within the ranges provided herein to balance changes without departing from the scope of this disclosure. It will further be appreciated that d and e may each independently be an integer value or a fractional value without departing from the scope of this disclosure.

In some embodiments, the second metal halide compound comprises a compound of the formula:

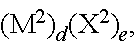

where:
M² is an alkali metal, an alkaline earth metal, or a transition metal;
X² is Cl, Br, F, or I;
d is 1 to 6; and
e is 1 to 6.

In some embodiments, M² is Li, Na, K, Mg, Ca, Sn, Al, Si, B, or Ga.

In some embodiments, the second metal halide compound comprises at least one of SnCl₂, SnCl₄, AlCl₃, LiCl, NaCl, KCl, or any combination thereof.

In some embodiments, the third metal halide compound comprises a compound of the formula:

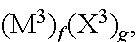

where:
M³ is a third metal;
X³ is a third halide;
f is 1 to 6; and
g is 1 to 6.

For brevity, it will be appreciated that f and g may vary within the ranges provided herein to balance changes without departing from the scope of this disclosure. It will further be appreciated that f and g may each independently be an integer value or a fractional value without departing from the scope of this disclosure.

In some embodiments, the third metal halide compound comprises a compound of the formula:

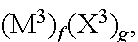

where:
M³ is an alkali metal, an alkaline earth metal, or a transition metal;
X³ is Cl, Br, F, or I;
f is 1 to 6; and
g is 1 to 6.

In some embodiments, M³ is Li, Na, K, Mg, Ca, Sn, Al, Si, B, or Ga.

In some embodiments, the third metal halide compound comprises at least one of SnCl₂, SnCl₄, AlCl₃, LiCl, NaCl, KCl, or any combination thereof.

In some embodiments, the reagent comprises 1 mol % to 99 mol % of the first metal halide compound based on a total moles of the reagent. In some embodiments, the reagent comprises 1 mol % to 90 mol %, 1 mol % to 80 mol %, 1 mol % to 70 mol %, 1 mol % to 60 mol %, 1 mol % to 50 mol %, 1 mol % to 40 mol %, 1 mol % to 30 mol %, 1 mol % to 20 mol %, 1 mol % to 10 mol %, 10 mol % to 99 mol %, 20 mol % to 99 mol %, 30 mol % to 99 mol %, 40 mol % to 99 mol %, 50 mol % to 99 mol %, 60 mol % to 99 mol %, 70 mol % to 99 mol %, 80 mol % to 99 mol %, or 90 mol % to 99 mol % of the first metal halide compound based on a total moles of the reagent.

In some embodiments, the reagent comprises 1 mol % to 99 mol % of the second metal halide compound based on a total moles of the reagent. In some embodiments, the reagent comprises 1 mol % to 90 mol %, 1 mol % to 80 mol %, 1 mol % to 70 mol %, 1 mol % to 60 mol %, 1 mol % to 50 mol %, 1 mol % to 40 mol %, 1 mol % to 30 mol %, 1 mol % to 20 mol %, 1 mol % to 10 mol %, 10 mol % to 99 mol %, 20 mol % to 99 mol %, 30 mol % to 99 mol %, 40 mol % to 99 mol %, 50 mol % to 99 mol %, 60 mol % to 99 mol %, 70 mol % to 99 mol %, 80 mol % to 99 mol %, or 90 mol % to 99 mol % of the second metal halide compound based on a total moles of the reagent.

In some embodiments, the reagent comprises 1 mol % to 99 mol % of the third metal halide compound based on a total moles of the reagent. In some embodiments, the reagent comprises 1 mol % to 90 mol %, 1 mol % to 80 mol %, 1 mol % to 70 mol %, 1 mol % to 60 mol %, 1 mol % to 50 mol %, 1 mol % to 40 mol %, 1 mol % to 30 mol %, 1 mol % to 20 mol %, 1 mol % to 10 mol %, 10 mol % to 99 mol %, 20 mol % to 99 mol %, 30 mol % to 99 mol %, 40 mol % to 99 mol %, 50 mol % to 99 mol %, 60 mol % to 99 mol %, 70 mol % to 99 mol %, 80 mol % to 99 mol %, or 90 mol % to 99 mol % of the third metal halide compound based on a total moles of the reagent.

The reagent may have a melting point of 300° C. or less. For example, in some embodiments, a melting point of the reagent is a temperature of −20° C. to 300° C., or any range or subrange between −20° C. and 300° C. In some embodiments, a melting point of the reagent is a temperature of −20° C. to 290° C., −20° C. to 280° C., −20° C. to 270° C., −20° C. to 260° C., −20° C. to 250° C., −20° C. to 240° C., −20° C. to 230° C., −20° C. to 220° C., −20° C. to 210° C., −20° C. to 200° C., −20° C. to 190° C., −20° C. to 180° C., −20° C. to 170° C., −20° C. to 160° C., −20° C. to 150° C., −20° C. to 140° C., −20° C. to 130° C., −20° C. to 120° C., −20° C. to 110° C., −20° C. to 100° C., −20° C. to 90° C., −20° C. to 80° C., −20° C. to 70° C., −20° C. to 60° C., −20° C. to 50° C., −20° C. to 40° C., −20° C. to 30° C., −20° C. to 20° C., −20° C. to 10° C., −20° C. to 0° C., −20° C. to −10° C., −10° C. to 300° C., 0° C. to 300° C., 10° C. to 300° C., 20° C. to 300° C., 30° C. to 300° C., 40° C. to 300° C., 50° C. to 300° C., 60° C. to 300° C., 70° C. to 300° C., 80° C. to 300° C., 90° C. to 300° C., 100° C. to 300° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

At step 104, in some embodiments, the method comprises obtaining a metal oxide compound.

In some embodiments, the metal trioxide compound comprises a compound of the formula:

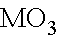

where:
M is W or Mo.

In some embodiments, the metal trioxide compound comprises at least one of WO₃, MoO₃, or any combination thereof.

In some embodiments, the metal oxide compound comprises a molybdenum oxide compound. In some embodiments, the metal oxide compound comprises a tungsten oxide compound. In some embodiments, the metal oxide compound does not comprise MoO₂. In some embodiments, the metal oxide compound does not comprise MoO. In some embodiments, the metal oxide compound does not comprise WO₂.

In some embodiments, instead of obtaining the metal trioxide compound, the step 104 comprises obtaining a molybdate compound. For example, in some embodiments, the molybdate compound comprises a compound of the formula:

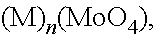

where:
M is a metal.

In some embodiments, M is at least one of an alkali metal, an alkaline earth metal, or any combination thereof. In some embodiments, for example, M is Na, Mg, or Al.

In some embodiments, n is sufficient to balance the charge of MoO₄. In some embodiments, n is at least 1. In some embodiments, n is a fractional value. In some embodiments, n is 1 to 2.

In some embodiments, the molybdate compound comprises Na₂MoO₄.

At step 106, in some embodiments, the method comprises contacting the reagent and the metal trioxide compound sufficient to form a reaction product.

The contacting may comprise bringing at least the reagent and the metal trioxide compound into immediate or close proximity, or into direct physical contact, under conditions sufficient to form the reaction product. In some embodiments, the contacting comprises mixing at least the reagent and the metal trioxide compound. In some embodiments, the contacting comprises combining at least the reagent and the metal trioxide compound in a vessel. In some embodiments, the contacting comprises stirring at least the reagent and the metal trioxide compound. In some embodiments, the contacting comprises agitating at least the reagent and the metal trioxide compound. In some embodiments, the contacting comprises solubilizing at least the reagent and the metal trioxide compound in at least one of a solution, a solvent, or a reaction medium. In some embodiments, the contacting comprises dissolving at least the reagent and the metal trioxide compound in at least one of a solution, a solvent, or a reaction medium. In some embodiments, the contacting comprises reacting at least the reagent and the metal trioxide compound. In some embodiments, the contacting comprises adding at least the reagent and the metal trioxide compound to a reaction vessel. In some embodiments, the contacting comprises combining at least the reagent and the metal trioxide compound in a reaction vessel. In some embodiments, the contacting proceeds when the reagent and the metal trioxide compound are present in a solid phase, and the resulting reaction product is present in a vapor and/or a gas phase.

In some embodiments, the contacting proceeds at a temperature of 300° C. or less. For example, in some embodiments, the contacting proceeds at a temperature of 20° C. to 300° C., or any range or subrange between 20° C. and 300° C. In some embodiments, the contacting proceeds at a temperature of 20° C. to 290° C., 20° C. to 280° C., 20° C. to 270° C., 20° C. to 260° C., 20° C. to 250° C., 20° C. to 240° C., 20° C. to 230° C., 20° C. to 220° C., 20° C. to 210° C., 20° C. to 200° C., 20° C. to 190° C., 20° C. to 180° C., 20° C. to 170° C., 20° C. to 160° C., 20° C. to 150° C., 20° C. to 140° C., 20° C. to 130° C., 20° C. to 120° C., 20° C. to 110° C., 20° C. to 100° C., 20° C. to 90° C., 20° C. to 80° C., 20° C. to 70° C., 20° C. to 60° C., 20° C. to 50° C., 20° C. to 40° C., 20° C. to 30° C., 30° C. to 300° C., 40° C. to 300° C., 50° C. to 300° C., 60° C. to 300° C., 70° C. to 300° C., 80° C. to 300° C., 90° C. to 300° C., 100° C. to 300° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

In some embodiments, the contacting proceeds at a pressure of 1 Torr or less. For example, in some embodiments, the contacting proceeds at a pressure of 0.01 Torr to 1 Torr, or any range or subrange between 0.01 Torr and 1 Torr. In some embodiments, the contacting proceeds at a pressure of 0.01 Torr to 0.9 Torr, 0.01 Torr to 0.8 Torr, 0.01 Torr to 0.7 Torr, 0.01 Torr to 0.6 Torr, 0.01 Torr to 0.5 Torr, 0.01 Torr to 0.4 Torr, 0.01 Torr to 0.3 Torr, 0.01 Torr to 0.2 Torr, 0.01 Torr to 0.1 Torr, 0.01 Torr to 0.09 Torr, 0.01 Torr to 0.08 Torr, 0.01 Torr to 0.07 Torr, 0.01 Torr to 0.06 Torr, 0.01 Torr to 0.05 Torr, 0.01 Torr to 0.04 Torr, 0.01 Torr to 0.03 Torr, 0.01 Torr to 0.02 Torr, 0.02 Torr to 1 Torr, 0.03 Torr to 1 Torr, 0.04 Torr to 1 Torr, 0.05 Torr to 1 Torr, 0.06 Torr to 1 Torr, 0.07 Torr to 1 Torr, 0.08 Torr to 1 Torr, 0.09 Torr to 1 Torr, 0.1 Torr to 1 Torr, 0.2 Torr to 1 Torr, 0.3 Torr to 1 Torr, 0.4 Torr to 1 Torr, 0.5 Torr to 1 Torr, 0.6 Torr to 1 Torr, 0.7 Torr to 1 Torr, 0.8 Torr to 1 Torr, or 0.9 Torr to 1 Torr.

In some embodiments, the reaction product comprises a molybdenum oxy halide compound. In some embodiments, the reaction product comprises a compound of the formula:

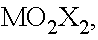

where:
M is W or Mo; and
X is a halide.

In some embodiments, the compound has a purity of at least 99% by weight as determined by inductively coupled plasma mass spectrometry (ICP-MS). In some embodiments, the compound has a purity of 99% to 99.99999%, or any range or subrange between 99% and 99.99999%, by weight as determined by inductively coupled plasma mass spectrometry. In some embodiments, the compound has a purity of 99.9% to 99.99999%, 99.99% to 99.99999%, 99.999% to 99.99999%, 99.9999% to 99.99999%, 99.9995% to 99.99999%, 99.9996% to 99.99999%, 99.9997% to 99.99999%, 99.9998% to 99.99999%, 99.9999% to 99.99999%, 99.99991% to 99.99999%, 99.99992% to 99.99999%, 99.99993% to 99.99999%, 99.99994% to 99.99999%, 99.99995% to 99.99999%, 99.99996% to 99.99999%, 99.99997% to 99.99999%, 99.99998% to 99.99999% by weight as determined by inductively coupled plasma mass spectrometry. In some embodiments, the compound has a purity of at least 99.99969% by weight as determined by inductively coupled plasma mass spectrometry.

In some embodiments, the reaction product is present in a vapor phase or a gas phase. In some embodiments, the reaction product is present in a liquid phase. In some embodiments, the reaction product is present in a solid phase. In some embodiments, the rection product is not present in a liquid phase. In some embodiments, the reaction product is not present in a solid phase.

In some embodiments, the reaction product does not comprise MoOCl₃. In some embodiments, the reaction product does not comprise MoOCl₄.

At step 108, in some embodiments, the method comprises flowing the reaction product from a vessel to a second vessel.

In some embodiments, the flowing comprises supplying the reaction product to the second vessel. In some embodiments, the flowing comprises pumping the reaction product from the vessel to the second vessel. In some embodiments, the flowing comprises introducing the reaction product into the second vessel. In some embodiments, the flowing comprises conveying the reaction product from the vessel to the second vessel. In some embodiments, the flowing comprises drawing the reaction product, for example, under vacuum, into the second vessel. In some embodiments, the flowing comprises flowing the reaction product directly to the second vessel. In some embodiments, the reaction product flows through a conduit from the vessel to the second vessel. In some embodiments, the flowing comprises opening a valve so as to flow the reaction product from the vessel to the second vessel.

At step 110, in some embodiments, the method comprises condensing the reaction product in the second vessel.

In some embodiments, the condensing comprises condensing the reaction product in the second vessel sufficient to obtain a purified reaction product. In some embodiments, the condensing comprises condensing the reaction product in the second vessel sufficient to obtain the reaction product in a solid phase. In some embodiments, the condensing comprises condensing the reaction product in the second vessel sufficient to obtain the reaction product in a liquid phase. In some embodiments, the condensing comprises cooling the reaction product in the second vessel to a temperature sufficient to condense the reaction product. In some embodiments, the condensing comprises cooling the second vessel to a temperature sufficient to condense the reaction product. In some embodiments, the condensing comprises pressurizing or depressurizing the second vessel to a pressure sufficient to condense the reaction product. In some embodiments, the temperature and/or pressure sufficient for condensing the reaction product is a temperature and/or a pressure below the condensation conditions (e.g., temperature and/or pressure) for the reaction product.

In some embodiments, the condensing proceeds at a temperature of −10° C. to 20° C., or any range or subrange between-10° C. and 20° C. For example, in some embodiments, the condensing proceeds at a temperature −10° C. to 15° C., −10° C. to 10° C., −10° C. to 5° C., −10° C. to 0° C., −10° C. to −5° C., −5° C. to 20° C., 0° C. to 20° C., 5° C. to 20° C., 10° C. to 20° C., or 15° C. to 20° C.

In some embodiments, the condensing proceeds at a pressure of 1 Torr or less. For example, in some embodiments, the condensing proceeds at a pressure of 0.01 Torr to 1 Torr, or any range or subrange between 0.01 Torr and 1 Torr. In some embodiments, the condensing proceeds at a pressure of 0.01 Torr to 0.9 Torr, 0.01 Torr to 0.8 Torr, 0.0 1Torr to 0.7 Torr, 0.01 Torr to 0.6 Torr, 0.01 Torr to 0.5 Torr, 0.01 Torr to 0.4 Torr, 0.01 Torr to 0.3 Torr, 0.01 Torr to 0.2 Torr, 0.01 Torr to 0.1 Torr, 0.01 Torr to 0.09 Torr, 0.01 Torr to 0.08 Torr, 0.01 Torr to 0.07 Torr, 0.01 Torr to 0.06 Torr, 0.01 Torr to 0.05 Torr, 0.01 Torr to 0.04 Torr, 0.01 Torr to 0.03 Torr, 0.01 Torr to 0.02 Torr, 0.02 Torr to 1 Torr, 0.03 Torr to 1 Torr, 0.04 Torr to 1 Torr, 0.05 Torr to 1 Torr, 0.06 Torr to 1 Torr, 0.07 Torr to 1 Torr, 0.08 Torr to 1 Torr, 0.09 Torr to 1 Torr, 0.1 Torr to 1 Torr, 0.2 Torr to 1 Torr, 0.3 Torr to 1 Torr, 0.4 Torr to 1 Torr, 0.5 Torr to 1 Torr, 0.6 Torr to 1 Torr, 0.7 Torr to 1 Torr, 0.8 Torr to 1 Torr, or 0.9 Torr to 1 Torr.

In some embodiments, the compound has a purity of at least 99% by weight as determined by inductively coupled plasma mass spectrometry (ICP-MS). In some embodiments, the compound has a purity of 99% to 99.99999%, or any range or subrange between 99% and 99.99999%, by weight as determined by inductively coupled plasma mass spectrometry. In some embodiments, the compound has a purity of 99.9% to 99.99999%, 99.99% to 99.99999%, 99.999% to 99.99999%, 99.9999% to 99.99999%, 99.9995% to 99.99999%, 99.9996% to 99.99999%, 99.9997% to 99.99999%, 99.9998% to 99.99999%, 99.9999% to 99.99999%, 99.99991% to 99.99999%, 99.99992% to 99.99999%, 99.99993% to 99.99999%, 99.99994% to 99.99999%, 99.99995% to 99.99999%, 99.99996% to 99.99999%, 99.99997% to 99.99999%, 99.99998% to 99.99999% by weight as determined by inductively coupled plasma mass spectrometry. In some embodiments, the compound has a purity of at least 99.99969% by weight as determined by inductively coupled plasma mass spectrometry.

In some embodiments, the reaction product comprises less than 200 ppb of at least one impurity, as determined by inductively coupled plasma mass spectrometry. For example, in some embodiments, the reaction product comprises less than 100 ppb, less than 50 ppb, less than 40 ppb, less than 30 ppb, less than 20 ppb, less than 10 ppb, or less than 1 ppb of the at least one impurity, as determined by inductively coupled plasma mass spectrometry.

In some embodiments, the at least one impurity comprises at least one of a metal component, a water, a hydrated compound, a water adduct, or any combination thereof. In some embodiments, the metal component comprises at least one of Ag, Al, Au, B, Ba, Be, Bi, Ca, Cd, Ce, Co, Cr, Cu, Fe, Ga, Ge, Hf, In, Ir, K, La, Li, Mg, Mn, Na, Nb, Ni, Pb, Pd, Pt, Rb, Rh, Ru, Sb, Se, Sn, Sr, Te, Th, Ti, Tl, U, V, W, Zn, Zr, or any combination thereof. In some embodiments, the compound comprises an anhydrous compound and/or an anhydrous reaction product.

In some embodiments, the method does not comprise a gas comprising chlorine. In some embodiments, the method does not comprise chlorine gas (Cl₂). In some embodiments, the method does not comprise at least one of air, water, oxygen, or any combination thereof.

In some embodiments, the method comprises obtaining a reagent. In some embodiments, the reagent comprises NaAlCl₄. In some embodiments, the method comprises obtaining a metal trioxide compound. In some embodiments, the metal trioxide compound comprises MoO₃. In some embodiments, the method comprises contacting the reagent and the metal trioxide compound sufficient to form a reaction product of the formula MoO₂Cl₂.

Some embodiments relate to a composition. In some embodiments, the composition comprises a compound of the formula:

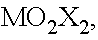

where:
M is W or Mo; and
X is a halide.

In some embodiments, the compound has a purity of at least 99% by weight as determined by inductively coupled plasma mass spectrometry (ICP-MS). In some embodiments, the compound has a purity of 99% to 99.99999%, or any range or subrange between 99% and 99.99999%, by weight as determined by inductively coupled plasma mass spectrometry. In some embodiments, the compound has a purity of 99.9% to 99.99999%, 99.99% to 99.99999%, 99.999% to 99.99999%, 99.9999% to 99.99999%, 99.9995% to 99.99999%, 99.9996% to 99.99999%, 99.9997% to 99.99999%, 99.9998% to 99.99999%, 99.9999% to 99.99999%, 99.99991% to 99.99999%, 99.99992% to 99.99999%, 99.99993% to 99.99999%, 99.99994% to 99.99999%, 99.99995% to 99.99999%, 99.99996% to 99.99999%, 99.99997% to 99.99999%, 99.99998% to 99.99999% by weight as determined by inductively coupled plasma mass spectrometry. In some embodiments, the compound has a purity of at least 99.99969% by weight as determined by inductively coupled plasma mass spectrometry.

In some embodiments, the composition comprises less than 200 ppb of at least one impurity, as determined by inductively coupled plasma mass spectrometry. For example, in some embodiments, the composition comprises less than 100 ppb, less than 50 ppb, less than 40 ppb, less than 30 ppb, less than 20 ppb, less than 10 ppb, or less than 1 ppb of the at least one impurity, as determined by inductively coupled plasma mass spectrometry.

In some embodiments, the at least one impurity comprises at least one of a metal component, a water, a hydrated compound, a water adduct, or any combination thereof. In some embodiments, the metal component comprises at least one of Ag, Al, Au, B, Ba, Be, Bi, Ca, Cd, Ce, Co, Cr, Cu, Fe, Ga, Ge, Hf, In, Ir, K, La, Li, Mg, Mn, Na, Nb, Ni, Pb, Pd, Pt, Rb, Rh, Ru, Sb, Se, Sn, Sr, Te, Th, Ti, Tl, U, V, W, Zn, Zr, or any combination thereof. In some embodiments, the compound comprises an anhydrous compound and/or an anhydrous reaction product.

In some embodiments, the compound is not a reaction product of molybdenum reagent and chlorine gas (Cl₂). In some embodiments, the compound is not a reaction product of molybdenum oxide compound and chlorine gas. In some embodiments, the compound is not a reaction product of MoO₃ and chlorine gas. In some embodiments, the compound is not a reaction product of MoO₂ and chlorine gas. In some embodiments, the composition does not comprise MoOCl₃. In some embodiments, the composition does not comprise MoOCl₄.

Some embodiments relate to a system. In some embodiments, the system comprises a vessel. In some embodiments, the vessel is configured for delivering a precursor vapor to a vapor deposition apparatus. In some embodiments, the vessel comprises or contains a precursor. In some embodiments, the precursor comprises any one or more of the reaction products disclosed herein. For example, in some embodiments, the precursor comprises a compound of the formula:

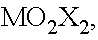

where:
M is W or Mo; and
X is a halide.

In some embodiments, the precursor is contained in the vessel at a temperature and a pressure sufficient for the compound to have a density of 4 g/cm³ or less. In some embodiments, the precursor is contained in the vessel at a temperature and a pressure sufficient for the compound to have a density of 3 g/cm³ to 4 g/cm³, 3 g/cm³ to 3.9 g/cm³, 3 g/cm³ to 3.8 g/cm³, 3 g/cm³ to 3.7 g/cm³, 3 g/cm³ to 3.6 g/cm³, 3 g/cm³ to 3.5 g/cm³, 3 g/cm³ to 3.4 g/cm³, 3 g/cm³ to 3.3 g/cm³, 3 g/cm³ to 3.2 g/cm³, 3 g/cm³ to 3.1 g/cm³, 3.1 g/cm³ to 4 g/cm³, 3.2 g/cm³ to 4 g/cm³, 3.3 g/cm³ to 4 g/cm³, 3.4 g/cm³ to 4 g/cm³, 3.5 g/cm³ to 4 g/cm³, 3.6 g/cm³ to 4 g/cm³, 3.7 g/cm³ to 4 g/cm³, 3.8 g/cm³ to 4 g/cm³, or 3.9 g/cm³ to 4 g/cm³.

In some embodiments, the compound has a purity of at least 99% by weight as determined by inductively coupled plasma mass spectrometry (ICP-MS). In some embodiments, the compound has a purity of 99% to 99.99999%, or any range or subrange between 99% and 99.99999%, by weight as determined by inductively coupled plasma mass spectrometry. In some embodiments, the compound has a purity of 99.9% to 99.99999%, 99.99% to 99.99999%, 99.999% to 99.99999%, 99.9999% to 99.99999%, 99.9995% to 99.99999%, 99.9996% to 99.99999%, 99.9997% to 99.99999%, 99.9998% to 99.99999%, 99.9999% to 99.99999%, 99.99991% to 99.99999%, 99.99992% to 99.99999%, 99.99993% to 99.99999%, 99.99994% to 99.99999%, 99.99995% to 99.99999%, 99.99996% to 99.99999%, 99.99997% to 99.99999%, 99.99998% to 99.99999% by weight as determined by inductively coupled plasma mass spectrometry. In some embodiments, the compound has a purity of at least 99.99969% by weight as determined by inductively coupled plasma mass spectrometry.

In some embodiments, the compound is not a reaction product of molybdenum reagent and chlorine gas (Cl₂). In some embodiments, the compound is not a reaction product of molybdenum oxide compound and chlorine gas. In some embodiments, the compound is not a reaction product of MoO₃ and chlorine gas. In some embodiments, the compound is not a reaction product of MoO₂ and chlorine gas. In some embodiments, the composition does not comprise MoOCl₃. In some embodiments, the composition does not comprise MoOCl₄.

In some embodiments, the precursor is useful in a vapor deposition process. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

### Example 1

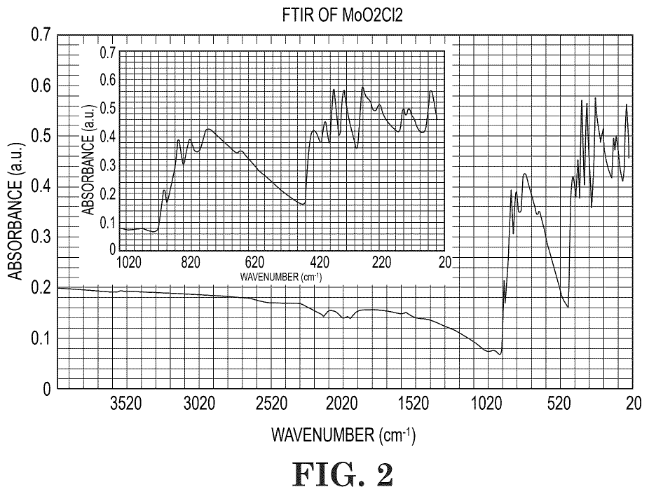

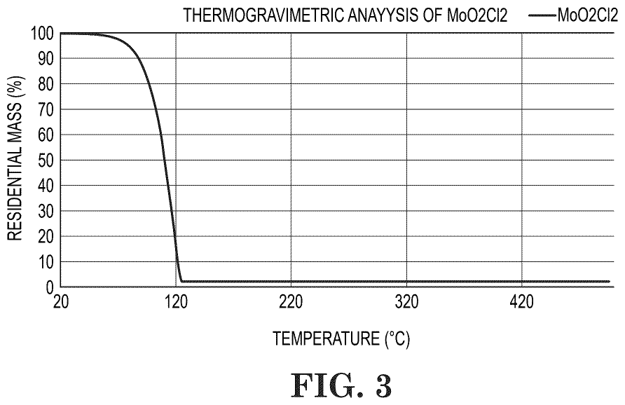

In a nitrogen-filled glovebox, NaCl (22.33 g, 382.1 mmol) and AlCl₃ (46.31 g, 347.3 mmol) were loaded into a 250-mL Schlenk flask equipped with a magnetic stir bar and heated to 170° C. with stirring for 1 hour, resulting in the formation of NaAlCl₄ as a dark brown liquid. The mixture was cooled to room temperature, forming a white solid, and the reaction flask heated to 170° C. under reduced pressure for a period of 2 hours to remove unreacted AlCl₃. The reaction flask was again cooled to room temperature prior to being loaded with MoO₃ (25.00 g, 173.7 mmol). The reaction mixture was placed under N₂ purge gas on a Schlenk line, outfitted with a porous inline-fritted distillation adapter packed with glass wool, a 60-degree bend adapter, and 250-mL collection flask. The adapter and supporting glassware were wrapped with heating tape and covered with aluminum foil. The apparatus was placed under reduced pressure, achieving a baseline of 90 mTorr. The collection flask was cooled using liquid nitrogen and the reaction pot heated to 185° C. using a heating mantle. Upon reaching operating temperature the reaction was heated for a period of one hour, whereby, MoO₂Cl₂ was observed in the collection flask as a microcrystalline peach-colored solid. At this point heating was discontinued, the collection flask was transferred to a nitrogen-filled glovebox, and the isolated MoO₂Cl₂ was collected for a total mass of 30.95 g, 89.62% yield. FTIR, TGA, and PXRD profiles were consistent with the synthesis of the target molecule. FIG. 2 is a Fourier-Transform Infrared (FTIR) spectrum for MoO₂Cl₂, according to some embodiments. FIG. 3 is a graphical view of a thermogravimetric analysis (TGA) for MoO₂Cl₂, according to some embodiments.

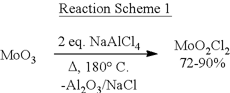

### Example 2

In a nitrogen-filled glovebox, a 4-neck 2 L Schlenk flask equipped with a magnetic stir bar, glass stoppers, and gas inlet adapter was loaded with NaCl (446.6 g, 7.642 mol) and AICI3 (926.2 g, 6.947 mol). The resulting off-white matrix was mixed with a spatula to homogenize the flask contents and then heated to 160° C. with stirring using a heating mantle. Upon melting, the mixture presented as a dark brown/black liquid with microcrystalline AlCl₃ visible at the top of the reaction flask and was stirred at 160° C. for 1 hour. At this point, the flask was placed under reduced pressure for one hour to remove unreacted AlCl₃ that had condensed on the top hemisphere of the flask. The heating was suspended and, upon cooling the NaAlCl₄ melt to room temperature, MoO₃ (500.0 g, 3.473 mol) was added directly to the solidified NaAlCl₄ matrix.

The flask containing the combined NaAlCl₄/MoO₃ mixture was brought out of the glovebox and placed on the Schlenk line under an atmosphere of N₂ and adapted to a short-path (60° bend) adapter equipped with inline glass fritted filter (SAFC PN: Z107476) and a 4-neck 2 L collection flask, which was equipped with a U-joint and 1 L secondary collection flask. The combined apparatus was placed under reduced pressure to achieve a baseline pressure of 55 mTorr. The apparatus was wrapped with heat tape, equipped with a heating mantle and J-CHEM dual channel temperature controller, and covered with Aluminum foil. The 2 L collection flask was cooled using a liquid nitrogen bath, the connecting joints heated to 120° C., and the reaction flask heated to 185° C., whereby, as the heating mantle temperature rose the internal pressure began to rise (65 mTorr @ 170° C. to 170 mTorr @ 185° C.) and a bright orange/peach colored solid was observed in 2 L primary collection flask. The apparatus was placed under static vacuum and the reaction continued under these conditions for 54 mins, at which point the heating was discontinued, the apparatus was cooled to room temperature and placed under an N₂ atmosphere. The primary and secondary flasks were brought into a nitrogen-filled glovebox and the combined collections placed in a tared 1 L bottle. MoO₂Cl₂ was collected as a peach microcrystalline solid. Total Yield: 497.21 g, 71.99%. PXRD analysis is consistent with isolation of the target molecule. M. P. (DSC): 179.80-180.74° C. The literature value for the melting point is 175° C., as shown in Chand, D. K.; Chakravarthy, R. D. Molybdenum Chloride Oxide. In Encyclopedia of Reagents for Organic Synthesis; John Wiley & Sons, Ltd, Ed.; John Wiley & Sons, Ltd: Chichester, UK, 2012. https://doi.org/10.1002/047084289X.rn01462.

TABLE 1
ICP-MS Comparison of raw materials to as-synthesized MoO₂Cl₂.

| | Detection | Compound | | | |
|---|---|---|---|---|---|
| Element | Limit | MoO2Cl2 | NaCl | MoO3 | AlCl3 |
| Aluminum | 100 | 568 | <MDL | 691 | <MDL |
| Antimony | 100 | <MDL | <MDL | <MDL | <MDL |
| Arsenic | 100 | <MDL | <MDL | 570 | <MDL |
| Barium | 100 | <MDL | <MDL | 292 | <MDL |
| Cadmium | 100 | <MDL | <MDL | <MDL | <MDL |
| Calcium | 1000 | <MDL | <MDL | 3280 | 25610 |
| Chromium | 100 | <MDL | <MDL | <MDL | <MDL |
| Cobalt | 100 | <MDL | 7930 | <MDL | <MDL |
| Copper | 100 | <MDL | <MDL | 4190 | <MDL |
| Gold | 100 | <MDL | <MDL | <MDL | <MDL |
| Iron | 100 | <MDL | <MDL | 1210 | 5670 |
| Lead | 100 | <MDL | <MDL | <MDL | 218 |
| Lithium | 200 | <MDL | <MDL | 184 | <MDL |
| Magnesium | 100 | <MDL | 3630 | 525 | 2440 |
| Manganese | 100 | <MDL | <MDL | <MDL | 537 |
| Nickel | 100 | <MDL | <MDL | <MDL | <MDL |
| potassium | 300 | <MDL | 34519 | 21400 | 1540 |
| Silver | 100 | <MDL | <MDL | <MDL | <MDL |
| Sodium | 100 | <MDL | <MDL | 2450 | <MDL |
| Tin | 100 | 444 | <MDL | 283 | <MDL |
| Titanium | 100 | 267 | <MDL | 423 | 4860 |
| Vanadium | 100 | 240 | <MDL | 362 | 729 |
| Tungsten | 100 | <MDL | <MDL | 151000 | <MDL |
| Zinc | 100 | <MDL | <MDL | <MDL | <MDL |
| Zirconium | 100 | <MDL | <MDL | <MDL | 159 |
| Total | | 1519 | 46079 | 186860 | 41763 |

* values in ppb
ICP-MS: Inductively Coupled Plasma Mass Spectroscopy
MDL: Machine Detection Limit

The MoO₂Cl₂ product shows much higher purity levels than those found in the materials used to produce the MoO₂Cl₂.

TABLE 2
PXRD summary of MoO₂Cl₂ collected on sample prepared in a sealed capillary at 25° C.

| | | | FWHM Left | Rel. Int. | | | | | | |
|---|---|---|---|---|---|---|---|---|---|---|
| No. | °2θ | °θ | [°2θ] | [%] | h | k | l | d-spacing [Å] | 1/(2 d) | 2 pi/d m |
| 1 | 12.6572 | 6.3286 | 0.1151 | 31.74 | | | | 6.98807 | 0.071551 | 0.89913 |
| 2 | 13.0556 | 6.5278 | 0.1151 | 100 | 0 | 0 | 2 | 6.77572 | 0.073793 | 0.927309 |
| 3 | 23.7706 | 11.8853 | 0.1535 | 21.51 | 1 | 1 | 1 | 3.74016 | 0.133684 | 1.679924 |
| 4 | 25.7899 | 12.89495 | 0.09 | 0.66 | 3 | 1 | 0 | 3.45172 | 0.144855 | 1.820306 |
| 5 | 26.2051 | 13.10255 | 0.1919 | 17.09 | 4 | 0 | 0 | 3.39796 | 0.147147 | 1.849105 |
| 6 | 30.2623 | 15.13115 | 0.09 | 0.44 | 3 | 1 | 1 | 2.951 | 0.169434 | 2.129172 |
| 7 | 32.565 | 16.2825 | 0.307 | 3.42 | 0 | 2 | 0 | 2.7474 | 0.18199 | 2.286957 |
| 8 | 39.6938 | 19.8469 | 0.1919 | 33.93 | 6 | 0 | 0 | 2.26887 | 0.220374 | 2.769302 |
| 9 | 40.3781 | 20.18905 | 0.2303 | 14.28 | 5 | 1 | 1 | 2.23198 | 0.224016 | 2.815072 |
| 10 | 46.5765 | 23.28825 | 0.307 | 2.82 | 0 | 2 | 2 | 1.94836 | 0.256626 | 3.224859 |
| 11 | 48.5335 | 24.26675 | 0.09 | 0.47 | 2 | 2 | 2 | 1.87427 | 0.266771 | 3.352337 |
| 12 | 52.161 | 26.0805 | 0.09 | 4.02 | 6 | 2 | 0 | 1.75214 | 0.285365 | 3.586006 |
| 13 | 52.4987 | 26.24935 | 0.2686 | 13.6 | 7 | 1 | 1 | 1.74166 | 0.287082 | 3.607584 |
| 14 | 52.9376 | 26.4688 | 0.09 | 2.19 | 1 | 3 | 1 | 1.72825 | 0.28931 | 3.635577 |
| 15 | 53.7576 | 26.8788 | 0.09 | 2.38 | 8 | 0 | 0 | 1.70381 | 0.29346 | 3.687727 |
| 16 | 56.2608 | 28.1304 | 0.09 | 0.48 | 3 | 1 | 3 | 1.63379 | 0.306037 | 3.845773 |
| 17 | 62.7438 | 31.3719 | 0.307 | 3.36 | 6 | 2 | 2 | 1.47966 | 0.337915 | 4.246371 |
| 18 | 63.279 | 31.6395 | 0.09 | 1.04 | 5 | 3 | 1 | 1.46843 | 0.3405 | 4.278846 |
| 19 | 64.2385 | 32.11925 | 0.09 | 0.32 | 8 | 0 | 2 | 1.44879 | 0.345116 | 4.33685 |
| 20 | 66.0324 | 33.0162 | 0.614 | 0.22 | 9 | 1 | 1 | 1.41371 | 0.353679 | 4.444465 |
| 21 | 68.5081 | 34.25405 | 1.535 | 0.58 | 10 | 0 | 0 | 1.36854 | 0.365353 | 4.591159 |
| 22 | 72.8175 | 36.40875 | 0.4605 | 2.15 | 7 | 3 | 1 | 1.2978 | 0.385267 | 4.841413 |
| 23 | 73.6858 | 36.8429 | 0.09 | 0.47 | 8 | 2 | 2 | 1.28464 | 0.389214 | 4.891009 |
| 24 | 76.059 | 38.0295 | 0.09 | 0.35 | 3 | 3 | 3 | 1.25035 | 0.399888 | 5.025141 |
| 25 | 77.4381 | 38.71905 | 0.09 | 0.24 | 0 | 4 | 2 | 1.23149 | 0.406012 | 5.1021 |
| 26 | 78.4883 | 39.24415 | 0.614 | 0.55 | 2 | 2 | 4 | 1.21762 | 0.410637 | 5.160219 |

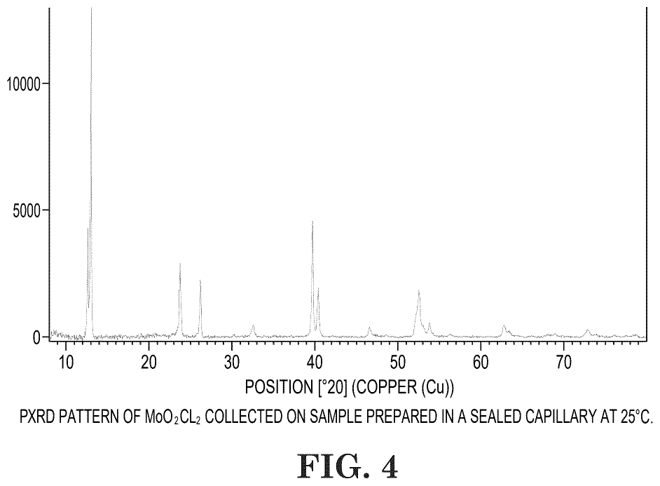

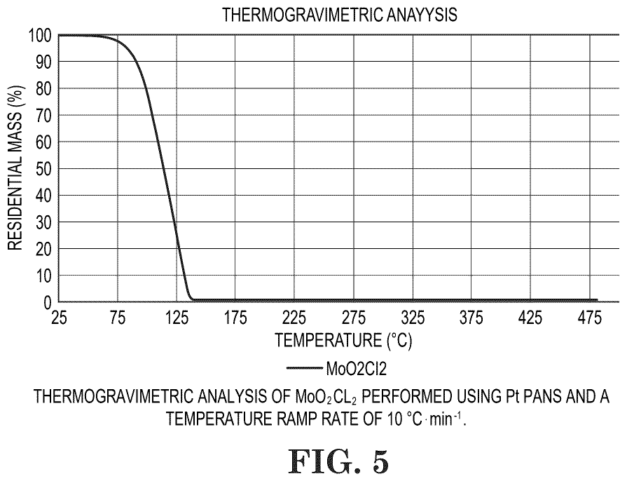

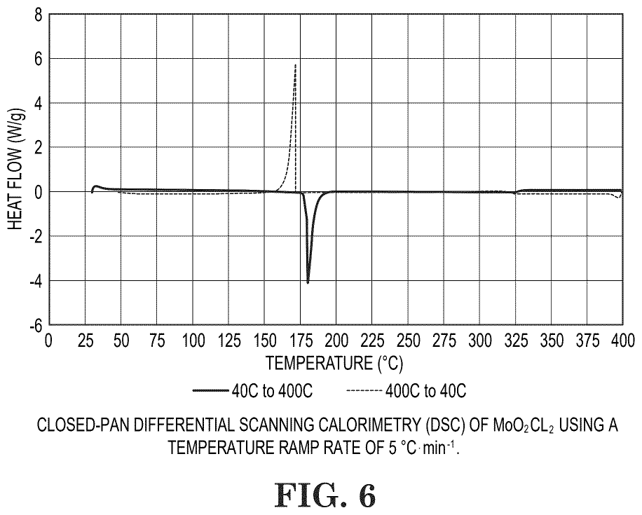

FIGS. 4 to 6 show testing data on the MoO₂Cl₂ produced. FIG. 4 is a Powder X-ray Diffraction (PXRD) pattern of MoO₂Cl₂ collected on sample prepared in a sealed capillary at 25° C. according to some embodiments. FIG. 5 is a ThermoGravimetric Analysis (TGA) of MoO₂Cl₂ performed using platinum pans and a temperature ramp rate of 10° C. per min according to some embodiments. FIG. 6 is a closed-pan Differential Scanning calorimetry (DSC) of MoO₂Cl₂ using a temperature ramp rate of 5° C. per min according to some embodiments.

### Aspects

Various Aspects are described below. It is to be understood that any one or more of the features recited in the following Aspect(s) can be combined with any one or more other Aspect(s).

Aspect 1. A method comprising:
obtaining a reagent,
   wherein the reagent comprises at least one of:
      a first metal halide compound,
      a second metal halide compound,
      a third metal halide compound, or
      any combination thereof;
obtaining a metal trioxide compound of the formula:

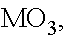

where:
   M is W or Mo; and
contacting the reagent and the metal trioxide compound sufficient to form a reaction product of the formula:

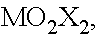

where:
   M is W or Mo; and
   X is a halide.

Aspect 2. The method according to Aspect 1, wherein the first metal halide compound comprises a compound of the formula:

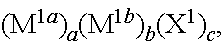

where:
   M^{1a} and M^{1b} are each independently a first metal;
   X¹ is a first halide;
   a is 0 to 6;
   b is 0 to 6; and
   c is at least 1.

Aspect 3. The method according to any one of Aspects 1-2, wherein the first metal halide compound comprises a compound of the formula:

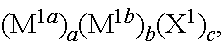

where:
   M^{1a} is an alkali metal, an alkaline earth metal, or a transition metal;
   M^{1b} is Sn or Al;
   X¹ is Cl, Br, F, or I;
   a is at least 1;
   b is at least 1; and
   c is at least 1.

Aspect 4. The method according to Aspect 3, wherein M^{1a} is Li, Na, K, Mg, or Ca.

Aspect 5. The method according to any one of Aspects 1-4, wherein the first metal halide compound comprises at least one of LiSnCl₃, NaSnCl₃, KSnCl₃, LiAlCl₄, NaAlCl₄, KAlCl₄, or any combination thereof.

Aspect 6. The method according to any one of Aspects 1-5, wherein the second metal halide compound comprises a compound of the formula:

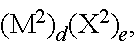

where:
   M² is a second metal;
   X² is a second halide;
   d is 1 to 6; and
   e is 1 to 6.

Aspect 7. The method according to any one of Aspects 1-6, wherein the second metal halide compound comprises a compound of the formula:

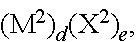

where:
   M² is an alkali metal, an alkaline earth metal, or a transition metal;
   X² is Cl, Br, F, or I;
   d is 1 to 6; and
   e is 1 to 6.

Aspect 8. The method according to Aspect 7, wherein M² is Li, Na, K, Mg, Ca, Sn, Al, Si, B, or Ga.

Aspect 9. The method according to any one of Aspects 1-8, wherein the second metal halide compound comprises at least one of SnCl₂, SnCl₄, AlCl₃, LiCl, NaCl, KCl, or any combination thereof.

Aspect 10. The method according to any one of Aspects 1-9, wherein the third metal halide compound comprises a compound of the formula:

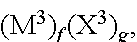

where:
   M³ is a third metal;
   X³ is a third halide;
   f is 1 to 6; and
   g is 1 to 6.

Aspect 11. The method according to any one of Aspects 1-10, wherein the third metal halide compound comprises a compound of the formula:

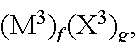

where:
   M³ is an alkali metal, an alkaline earth metal, or a transition metal;
   X³ is Cl, Br, F, or I;
   f is 1 to 6; and
   g is 1 to 6.

Aspect 12. The method according to Aspect 11, wherein M³ is Li, Na, K, Mg, Ca, Sn, Al, Si, B, or Ga.

Aspect 13. The method according to any one of Aspects 1-12, wherein the third metal halide compound comprises at least one of SnCl₂, SnCl₄, AlCl₃, LiCl, NaCl, KCl, or any combination thereof.

Aspect 14. The method according to any one of Aspects 1-13, wherein the reagent comprises the first metal halide compound and the second metal halide compound.

Aspect 15. The method according to Aspect 14, wherein the first metal halide compound and the second metal halide compound form a eutectic mixture.

Aspect 16. The method according to any one of Aspects 1-15, wherein the reagent comprises the first metal halide compound, the second metal halide compound, and the third metal halide compound.

Aspect 17. The method according to Aspect 16, wherein the first metal halide compound, the second metal halide compound, and the third metal halide compound form a eutectic mixture.

Aspect 18. The method according to any one of Aspects 1-17, wherein a melting point of the reagent is a temperature of 300° C. or less.

Aspect 19. The method according to any one of Aspects 1-18, wherein a melting point of the reagent is a temperature of −20° C. to 300° C.

Aspect 20. The method according to any one of Aspects 1-19, wherein the contacting proceeds at a temperature of 300° C. or less.

Aspect 21. The method according to any one of Aspects 1-20, wherein the contacting proceeds at a temperature of 20° C. to 300° C.

Aspect 22. The method according to any one of Aspects 1-21, wherein the contacting proceeds at a pressure of 1 Torr or less.

Aspect 23. The method according to any one of Aspects 1-22, wherein the contacting proceeds at a pressure of 0.01 Torr to 1 Torr.

Aspect 24. The method according to any one of Aspects 1-23, wherein the method does not comprise a gas comprising chlorine.

Aspect 25. The method according to any one of Aspects 1-24, further comprising:
flowing the reaction product from a vessel to a second vessel; and
condensing the reaction product in the second vessel.

Aspect 26. A composition comprising:
a compound of the formula:

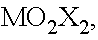

where:
   M is W or Mo; and
   X is a halide,
      wherein the compound has a purity of at least 99.99969% by weight as determined by inductively coupled plasma mass spectrometry (ICP-MS).

Aspect 27. The composition according to Aspect 26, wherein the composition comprises less than wherein the composition comprises less than 200 ppb of at least one impurity, as determined by ICP-MS.

Aspect 28. The composition according to any one of Aspects 26-27, wherein the at least one impurity comprises at least one of a metal component, a water, a hydrated compound, a water adduct, or any combination thereof.

Aspect 29. A system comprising:
a vessel,
   wherein the vessel is configured for delivering a precursor vapor to a vapor deposition apparatus;
   wherein the vessel comprises a precursor comprising a compound of the formula:

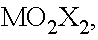

where:
   M is W or Mo; and
   X is a halide,
wherein the precursor is contained in the vessel at a temperature and a pressure sufficient for the compound to have a density of 4 g/cm³ or less;
wherein the compound has a purity of at least 99.99969% by weight as determined by inductively coupled plasma mass spectrometry (ICP-MS).

Aspect 30. The system according to Aspect 29, when the precursor is vaporized to form the precursor vapor and the precursor vapor is supplied to the vapor deposition apparatus to form a film, the film comprises less than 200 ppb of at least one impurity, as determined by ICP-MS.

What is claimed is:

1. A method comprising:
obtaining a reagent,
wherein the reagent comprises at least one of:
a first metal halide compound,
a second metal halide compound,
a third metal halide compound, or
any combination thereof;
obtaining a metal trioxide compound of the formula: 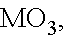
where:
M is W or Mo; and
contacting the reagent and the metal trioxide compound sufficient to form a reaction product of the formula: 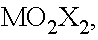
where:
M is W or Mo; and
X is a halide.

2. The method of claim 1, wherein the first metal halide compound comprises a compound of the formula: 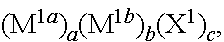
where:
M^{1a} and M^{1b} are each independently a first metal;
X¹ is a first halide;
a is 0 to 6;
b is 0 to 6; and
c is at least 1.

3. The method of claim 1, wherein the first metal halide compound comprises a compound of the formula: 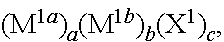
where:
M^{1a} is an alkali metal, an alkaline earth metal, or a transition metal;
M^{1b} is Sn or Al;
X¹ is Cl, Br, F, or I;
a is at least 1;
b is at least 1; and
c is at least 1.

4. The method of claim 3, wherein M^{1a} is Li, Na, K, Mg, or Ca.

5. The method of claim 1, wherein the first metal halide compound comprises at least one of LiSnCl₃, NaSnCl₃, KSnCl₃, LiAlCl₄, NaAlCl₄, KAlCl₄, or any combination thereof.

6. The method of claim 1, wherein the second metal halide compound comprises a compound of the formula: 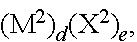
where:
M² is a second metal;
X² is a second halide;
d is 1 to 6; and
e is 1 to 6.

7. The method of claim 1, wherein the second metal halide compound comprises a compound of the formula: 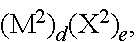
where:
M² is an alkali metal, an alkaline earth metal, or a transition metal;
X² is Cl, Br, F, or I;
d is 1 to 6; and
e is 1 to 6.

8. The method of claim 7, wherein M² is Li, Na, K, Mg, Ca, Sn, Al, Si, B, or Ga.

9. The method of claim 1, wherein the second metal halide compound comprises at least one of SnCl₂, SnCl₄, AlCl₃, LiCl, NaCl, KCl, or any combination thereof.

10. The method of claim 1, wherein the third metal halide compound comprises a compound of the formula: 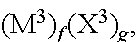
where:
M³ is a third metal;
X³ is a third halide;
f is 1 to 6; and
g is 1 to 6.

11. The method of claim 1, wherein the third metal halide compound comprises a compound of the formula: 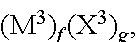
where:
M³ is an alkali metal, an alkaline earth metal, or a transition metal;
X³ is Cl, Br, F, or I;
f is 1 to 6; and
g is 1 to 6.

12. The method of claim 11, wherein M³ is Li, Na, K, Mg, Ca, Sn, Al, Si, B, or Ga.

13. The method of claim 1, wherein the third metal halide compound comprises at least one of SnCl₂, SnCl₄, AlCl₃, LiCl, NaCl, KCl, or any combination thereof.

14. The method of claim 1, wherein the reagent comprises the first metal halide compound and the second metal halide compound.

15. The method of claim 14, wherein the first metal halide compound and the second metal halide compound form a eutectic mixture.

16. The method of claim 1, wherein the reagent comprises the first metal halide compound, the second metal halide compound, and the third metal halide compound.

17. The method of claim 16, wherein the first metal halide compound, the second metal halide compound, and the third metal halide compound form a eutectic mixture.

18. The method of claim 1, wherein a melting point of the reagent is a temperature of 300° C. or less.

19. The method of claim 1, wherein a melting point of the reagent is a temperature of −20° C. to 300° C.

20. The method of claim 1, wherein the contacting proceeds at a temperature of 300° C. or less.

21. The method of claim 1, wherein the contacting proceeds at a temperature of 20° C. to 300° C.

22. The method of claim 1, wherein the contacting proceeds at a pressure of 1 Torr or less.

23. The method of claim 1, wherein the contacting proceeds at a pressure of 0.01 Torr to 1 Torr.

24. The method of claim 1, wherein the method does not comprise a gas comprising chlorine.

25. The method of claim 1, further comprising:
flowing the reaction product from a vessel to a second vessel; and
condensing the reaction product in the second vessel.

26. A composition comprising:
a compound of the formula: 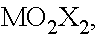
where:
M is W or Mo; and
X is a halide,
wherein the compound has a purity of at least 99.99969% by weight as determined by inductively coupled plasma mass spectrometry (ICP-MS).

27. The composition of claim 26, wherein the composition comprises less than 200 ppb of at least one impurity, as determined by ICP-MS.

28. The composition of claim 27, wherein the at least one impurity comprises at least one of a metal component, a water, a hydrated compound, a water adduct, or any combination thereof.

29. A system comprising:
a vessel,
wherein the vessel is configured for delivering a precursor vapor to a vapor deposition apparatus;
wherein the vessel comprises a precursor comprising a compound of the formula: 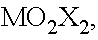
where:
M is W or Mo; and
X is a halide,
wherein the precursor is contained in the vessel at a temperature and a pressure sufficient for the compound to have a density of 4 g/cm³ or less;
wherein the compound has a purity of at least 99.99969% by weight as determined by inductively coupled plasma mass spectrometry (ICP-MS).

30. The system of claim 29, when the precursor is vaporized to form the precursor vapor and the precursor vapor is supplied to the vapor deposition apparatus to form a film, the film comprises less than 200 ppb of at least one impurity, as determined by ICP-MS.
